(19) United States
(12) Patent Application Publication
(10) Pub. No.: US 2009/0086461 A1
(43) Pub. Date: Apr. 2, 2009

(54) Shielding Apparatus and Manufacturing Method Thereof

(76) Inventor: Ki Min Lee, Jungnang-gu (KR)

Correspondence Address: SALIWANCHIK LLOYD & SALIWANCHIK;A PROFESSIONAL ASSOCIATION, PO Box 142950, GAINESVILLE, FL, 32614, US

(21) Appl. No.: 12/282,317

(22) PCT Filed: Dec. 14, 2006
(86) PCT No.: PCT/KR06/05463

§ 371 Date: Sep. 9, 2008

(30) Foreign Application Priority Data
Mar. 16, 2006 (KR) 10-2006-0024201

(51) Int. Cl. H05K 9/00

(52) U.S. Cl. 361/816; 29/592.1

(57) ABSTRACT

A shielding apparatus is provided. The shielding apparatus comprises a substrate on which an electronic device is mounted, a molding layer on the substrate, a conductor layer on a surface of the molding layer, and a ground member electrically connecting a ground terminal of the substrate with the conductor layer.

### TECHNICAL FIELD

The present invention relates to a shielding apparatus and a manufacturing method thereof.

### BACKGROUND ART

Mobile communication terminals such as a cell phone, a personal digital assistant (PDA) and a smart phone, a variety of communication equipments and media players have various kinds of electronic devices therein. The electronic devices are formed into an integrated module in a printed circuit board (PCB).

Particularly, a radio frequency (RF) integrated module is exposed to severe electromagnetic interference. The electromagnetic interference (EMI) has bad influences upon performances of the electronic devices constituting the integrated module.

The EMI means undesirable radiated emission (RE) or undesirable conducted emission (CE) of an electromagnetic signal from electronic devices.

The EMI causes problems in performances of adjacent electronic devices to deteriorate an integrated module and causes a malfunction of an apparatus including the electronic devices therein.

The CE is performed when electromagnetic noise mainly having frequency lower than 30 MHz is transmitted through a medium such as a signal line and a power line. On the contrary, the RE is performed when electromagnetic noise mainly having frequency greater than 30 MHz is radiated to the air. Accordingly, the RE has a wider radiation range than that of the CE.

Various researches are actively in progress to solve the above-mentioned problems and to protect electronic devices from external shocks.

FIGS. 1 and 2 are views illustrating a shielding apparatus and a manufacturing method thereof according to a related art.

Referring to FIGS. 1 and 2, a plurality of electronic devices 110 are mounted on a PCB 100 and a junction channel 102 is formed in the PCB 100.

Also, a junction part 142 which will be inserted into the junction channel 102 is formed in a shield can 140.

After the PCB 100 is fixed on a jig (S100), a solder paste 10 is discharged in the junction channel 102 of the PCB 100 using a dispenser 120 (S110).

Then, the junction part 142 of the shield can 140 is moved over the junction channel 102 of the PCB 100 and the shield can 140 is mounted on the PCB 100 (S120).

After that, the solder paste 10 is cured by a reflow treatment to couple the shield can 140 with the PCB 100 (S130).

In the shielding apparatus and the manufacturing method thereof, it is important to discharge a fixed amount of the solder paste 10 from the dispenser 120. If the amount of the solder paste 10 is excessive, the solder paste 10 may be conducted to an electronic device 110, which may lead to a malfunction of an integrated module.

Also, because the related art shielding apparatus is formed to have a structure that a shield can 140 is coupled with a PCB 100, it is difficult to miniaturize.

### DISCLOSURE OF INVENTION

### Technical Problem

The embodiment of the present invention provides a shielding apparatus capable of preventing electromagnetic interference, and a manufacturing method for the same.

The embodiment of the present invention provides a shielding apparatus capable of protecting an electronic device from an external shock, and a manufacturing method for the same.

### Technical Solution

The embodiment of the present invention provides a shielding apparatus comprising a substrate on which an electronic device is mounted, a molding layer on the substrate, a conductor layer on a surface of the molding layer, and a ground member electrically connecting a ground terminal of the substrate with the conductor layer.

The embodiment of the present invention provides a manufacturing method of a shielding apparatus, the method comprises preparing a substrate on which an electronic device is mounted, forming a ground member electrically connected to a ground terminal of the substrate, forming a molding layer to cover the electronic device and a portion of the ground member, and forming a conductor layer on the molding layer such that the conductor layer is electrically connected to the ground member.

The embodiment of the present invention provides a shielding apparatus comprising a substrate on which an electronic device is mounted, a molding layer on the substrate to cover the electronic device, a conductor layer on the molding layer, and a conducting material formed to pass through the molding layer and connect the substrate with the conductor layer.

The embodiment of the present invention provides a shielding apparatus comprising a substrate on which an electronic device is mounted, a molding layer on the substrate to cover the electronic device, a conductor layer on the molding layer, and a wire in the molding layer to connect the substrate with the conductor layer.

### ADVANTAGEOUS EFFECTS

According to the embodiment of the present invention, it is possible to protect an electronic device from an external shock and to effectively prevent electromagnetic interference.

### BRIEF DESCRIPTION OF THE DRAWINGS

FIGS. 1 and 2 are views illustrating a shielding apparatus and a manufacturing method thereof according to a related art;

FIG. 3 is a cross-sectional view illustrating a shielding apparatus according to a first embodiment of the present invention;

FIG. 4 is a cross-sectional view illustrating a shielding apparatus according to a second embodiment of the present invention; and

FIG. 5 is a flow chart illustrating a manufacturing method of a shielding apparatus according to an embodiment of the present invention.

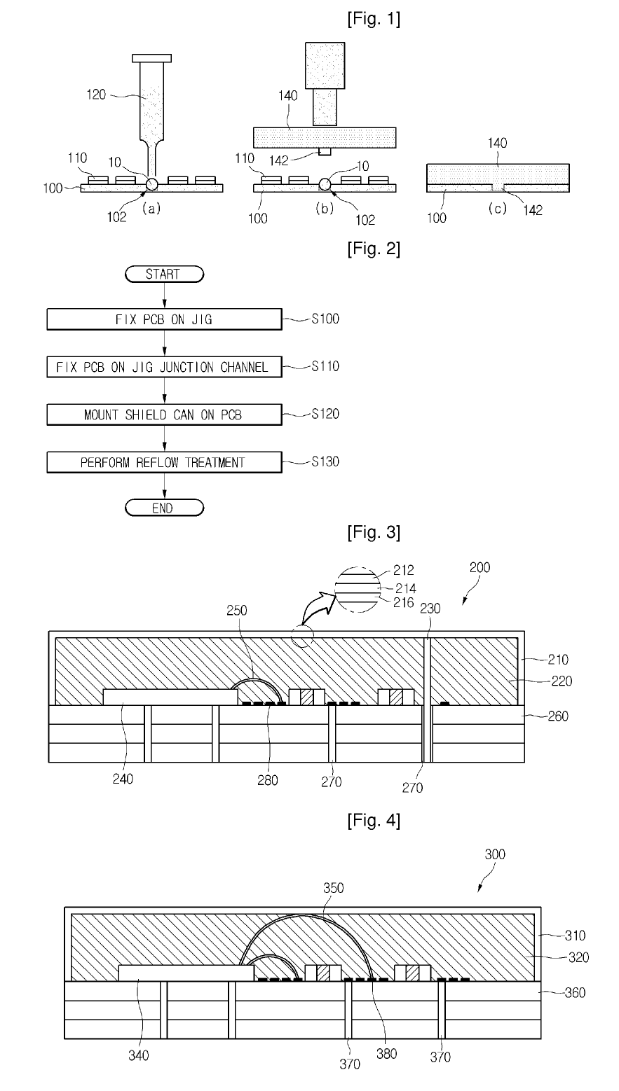

### BEST MODE FOR CARRYING OUT THE INVENTION

Hereinafter, preferred embodiments of the present invention will be described in detail with reference to accompanying drawings.

FIG. 3 is a cross-sectional view illustrating a shielding apparatus according to a first embodiment of the present invention.

Referring to FIG. 3, a shielding apparatus 200 according to the first embodiment of the present invention includes a molding layer 220, a conductor layer 210 and a metal pin 230.

Various metal patterns 280 such as a metal pattern for grounding, a metal pattern for bonding and a metal pattern for signal transmission are formed in a substrate on which the shielding apparatus 200 is mounted. Also, an electronic device 240 is mounted on a surface of the substrate. The electronic device 240 is connected to the metal pattern 280 through a wire 250.

A PCB or a low temperature co-fired ceramic (LTCC) substrate may be used as the substrate 260.

The LTCC substrate is formed using a co-firing processing of a ceramic and a metal at a temperature range of 800˜1000° C. That is, after mixing a ceramic and a glass of a low melting point and forming a green sheet having an adequate permittivity, a conductive paste made mainly from silver or copper is printed and stacked on the green sheet, and then the LTCC substrate is formed.

The LTCC substrate has a multi-layered structure and passive devices such as a capacitor, a resistor and an inductor are formed in the LTCC substrate to be conducted to a metal pattern or electronic devices on a surface of the substrate through via holes, which makes it possible to realize a highly integrated, slim and lightweight shielding apparatus.

The molding layer 220 protects electronic devices 240 from an external shock and fixes bonding parts to prevent short circuit between electronic devices 240.

The molding layer 220 may be formed of a synthetic resin such as epoxy and silicon. The molding layer 220 may be formed using a dam and fill molding or a transfer molding.

The transfer molding is a molding method with a thermosetting resin, where a thermosetting resin that has been plasticized in a heating chamber is pressed into a mold cavity. In the dam and fill molding, on the other hand, after forming a partition wall around the molding region, a viscous thermosetting resin fills the molding region and then is cured. After that, the partition wall is removed.

Meanwhile, the molding layer 220 is formed to have a height of 500˜1000□ up from a top surface of the substrate.

The conductor layer 210 may be formed on a surface of the molding layer 220 using plating. The conductor layer 210 may be formed on an entire surface of the molding layer 220 including a top surface and side surfaces of the molding layer 220. The conductor layer 210 may also be formed only on a portion of the molding layer 220 according to a predetermined pattern.

The conductor layer 210 is a shield layer serving as a metal can. Because the conductor layer 210 is formed using plating, it may have a fine thickness in comparison with a metal can.

For example, the conductor layer 210 may be formed by sputtering a metal under the atmosphere of an injected active gas or depositing a metal film using a high current supplied through an electrode.

According to an embodiment of the present invention, the conductor layer 210 may be a multiple layer for reasons of adhesion to the molding layer 220 and solidity of the resultant structure. The conductor layer 210 may also include sequentially plated layers 216, 214 and 212 of Cu, Ni and Au.

The conductor layer 210 has a thickness of approximately 20□ whereas the layers of Cu 216, Ni 214 and Au 212 have thicknesses of approximately 10˜15□, 5˜10□ and 0.1˜0.5□, respectively.

The Cu layer 216 provides an excellent RF shielding effect, the Ni layer 214 provides an excellent interlayer adhesion and the Au layer 212 provides an excellent solidity to protect the conductor layer 210 against damage caused by a shock or a friction.

A thickness of the conductor layer 210 may be determined in consideration of a skin depth. The skin depth is an index of a depth where a high frequency signal flows along a surface of a conductor. The skin depth varies with the conductor and a frequency band.

That is, the conductor layer 210 may be formed to be thicker than the skin depth so that a high frequency signal therein may not be radiated out of the conductor layer, and thus an EMI may not be caused. For example, when the high frequency signal has a frequency of 1 GHz, the Au layer has a skin depth of 2.49□, the Cu layer has a skin depth of 3.12□ and the Ni layer has a skin depth of 4.11□.

Therefore, a shielding apparatus according to the first embodiment of the present invention has the following advantages: a size thereof is significantly decreased; a physical adhesive strength is enhanced; and an EMI is prevented effectively.

Meanwhile, the conductor layer 210 is grounded in order to discharge shielded electromagnetic wave. The conductor layer 210 may be electrically connected to a metal pattern 280 for grounding of the substrate 260, through a metal pin 230.

That is, the metal pin 230 is formed through a molding layer 220 and is electrically connected to both the conductor layer 210 and the metal pattern 280 for grounding of the substrate 260.

The metal pin 230 may be formed to penetrate the metal pattern 280 for grounding and be fixed on the substrate 260. The metal pin 230 may also be formed to be inserted and fixed in a via hole 270 that is electrically connected to the metal pattern 280 for grounding of the substrate 260 as shown in FIG. 3.

FIG. 4 is a cross-sectional view illustrating a shielding apparatus according to a second embodiment of the present invention.

Referring to FIG. 4, the shielding apparatus includes a molding layer 320, a conductor layer 310 and a wire 350.

The conductor layer 310 is electrically connected to the metal pattern 380 for grounding through a wire.

The conductor layer 310 may be formed on an entire surface of the molding layer 320 including a top surface and side surfaces of the molding layer 320. The conductor layer 310 may also be formed only on a portion of the molding layer 320 according to a predetermined pattern.

The wire 350 connects a ground terminal of an electronic device 340 to a metal pattern 380 on the substrate 360. A length of the wire 350 is adjusted such that the wire 350 has a parabolic shape and a portion of the wire 350 is in contact with the conductor layer 310 in order to electrically connect the wire 350 to the conductor layer 310.

Also, although not shown, a portion of the wire 350 may be in contact with the conductor layer 310 whereas another portion of the wire 350 is in contact with a via hole that is electrically connected to a metal pattern 380 for grounding.

The wire 350 may be formed of gold. A length of the wire 350 is adjusted such that the wire 350 may not extrude out of the conductor layer 310.

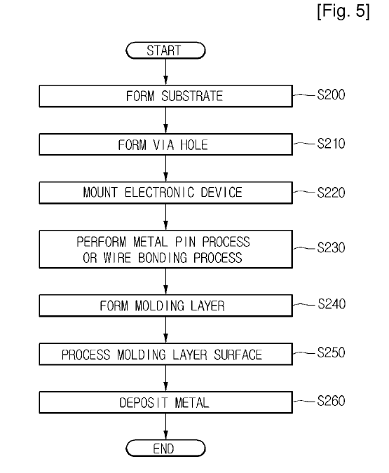

Hereinafter, manufacturing methods of electromagnetic shielding apparatuses 200 and 300 according to the first and second embodiments of the present invention will now be described. The manufacturing methods of electromagnetic shielding apparatuses according to the first and second embodiments of the present invention will be described together with reference to FIG. 5 because their manufacturing processes are very similar.

FIG. 5 is a flow chart illustrating a manufacturing method of shielding apparatuses 200 and 300 according to an embodiment of the present invention.

In the first place, a manufacturing method of a shielding apparatus 200 according to the first embodiment of the present invention is described as follows.

A substrate 260 having a multi-layered structure is formed and metal patterns 280 including a metal pattern for grounding is formed on the substrate (S200). Also, a via hole 270 is formed in the substrate 260 (S210).

Various electronic devices 240 such as a passive device and an active device are mounted on the substrate 260 (S220). Also, a process for bonding a wire 250 is performed on the substrate 260.

After that, a metal pin process is performed. The metal pin 230 may be inserted into the via hole 270 for grounding of the substrate 260 using a hammering (S230).

Then, after forming a molding layer 220 to a predetermined height using a dam and fill molding or a transfer molding (S240), a portion of the metal pin 230 extruding out of the molding layer 220 is cut off in close proximity to a top surface of the molding layer 220.

Afterwards, a surface processing such as grinding and polishing is performed on the molding layer 220 (S250).

The surface processing is designed for making a surface of the molding layer 220 smooth so that a plated conductor layer 210 could strongly adhere to a surface of the molding layer 220. When a surface of the molding layer 220 is processed, a portion of the metal pin 230 extruding out of the surface of the molding layer 220 may be processed together, so that the metal pin 230 does not extrude out of the conductor layer 210.

Meanwhile, the grinding or polishing may be omitted, and the cutting off of the portion of the metal pin 230 may also be omitted.

When the metal pin 230 is formed to be lower than the molding layer 220, the molding layer 220 may be grinded or polished so that a surface of the molding layer 220 may be smooth and a portion of the metal pin 230 may extrude out of the molding layer 220. Thereby, the conductor layer 210, when it is deposited, may be electrically connected to the metal pin 230.

Finally, copper 216, nickel 214 and gold 212 are sequentially deposited on the surface of the molding layer 220 to form a multi-layered conductor layer 210 and thus to form a shielding apparatus 200 according to an embodiment of the present invention (S260).

In the next place, a manufacturing method of a shielding apparatus 300 according to the second embodiment of the present invention is described as follows.

A substrate 360 having a multi-layered structure is formed and metal patterns 380 including a metal pattern for grounding is formed on the substrate (S200). Also, a via hole 370 is formed in the substrate 360 (S210).

Various electronic devices 340 such as a passive device and an active device are mounted on the substrate 360 (S220). Also, a process for bonding a wire is performed on the substrate 260.

Here, the wire is formed so that both terminals of the wire 350 are connected to a ground terminal of an electronic device 340 and a metal pattern 380 for grounding of the substrate 360, respectively. Also, the wire is formed to have an adequate length so that a portion of the wire 350 may be electrically connected to a conductor layer 310 formed outside the molding layer 320 afterwards (S230).

Then, after forming a molding layer 320 to a predetermined height using a dam and fill molding or a transfer molding (S240), a portion of the wire 350 extruding out of the molding layer 320 is cut off in close proximity to a top surface of the molding layer 320.

Afterwards, a surface processing such as grinding and polishing is performed on the molding layer 320 (S250).

The surface processing is designed for making a surface of the molding layer 320 smooth so that a plated conductor layer 310 could strongly adhere to a surface of the molding layer 320. When a surface of the molding layer 320 is grinded or polished, a portion of the wire 350 extruding out of the surface of the molding layer 320 may be grinded or polished together, so that the wire 350 does not extrude out of the conductor layer 310.

Meanwhile, the grinding or polishing may be omitted, and the cutting off of the portion of the wire 350 may also be omitted.

When the wire 350 is formed to be lower than the molding layer 320, the molding layer 320 may be grinded or polished so that a surface of the molding layer 320 may be smooth and a portion of the wire 350 may extrude out of the molding layer 320. Thereby, the conductor layer 310, when it is deposited, may be electrically connected to the wire 350.

Finally, copper 216, nickel 214 and gold 212 are sequentially deposited on a surface of the molding layer 320 to form a multi-layered conductor layer 310 and thus to form a shielding apparatus 300 according to an embodiment of the present invention (S260).

### MODE FOR THE INVENTION

While the present invention has been described and illustrated herein with reference to the preferred embodiments thereof, it will be apparent to those skilled in the art that various modifications and variations can be made therein without departing from the spirit and scope of the invention.

Thus, it is intended that the present invention cover the modifications and variations of this invention that come within the scope of the appended claims and their equivalents.

### INDUSTRIAL APPLICABILITY

The embodiment of the present invention can be applied to an electronic apparatus mounting an electronic device therein and a manufacturing method thereof.

1. A shielding apparatus comprising:
a substrate on which an electronic device is mounted;
a molding layer on the substrate;
a conductor layer on a surface of the molding layer; and
a ground member electrically connecting a ground terminal of the substrate with the conductor layer.

2. The shielding apparatus according to claim 1, wherein the ground member is formed to pass through the molding layer.

3. The shielding apparatus according to claim 1, wherein the ground member comprises a metal pin.

4. The shielding apparatus according to claim 1, wherein the ground member comprises a wire.

5. The shielding apparatus according to claim 1, wherein the ground member electrically connects the electronic device, the conductor layer and the ground terminal.

6. The shielding apparatus according to claim 1, wherein the conductor layer is formed on the surface including a top surface and side surfaces of the molding layer.

7. The shielding apparatus according to claim 1, wherein the conductor layer is formed on a portion of the molding layer according to a predetermined pattern.

8. The shielding apparatus according to claim 1, wherein the ground terminal comprises one of a via hole and a metal pattern.

9. The shielding apparatus according to claim 1, wherein a plurality of layers made from a plurality of metals constitute the conductor layer.

10. The shielding apparatus according to claim 1, wherein the conductor layer is formed of copper, nickel and gold.

11. A manufacturing method of a shielding apparatus, the method comprising:
preparing a substrate on which an electronic device is mounted;
forming a ground member electrically connected to a ground terminal of the substrate;
forming a molding layer to cover the electronic device and a portion of the ground member; and
forming a conductor layer on the molding layer such that the conductor layer is electrically connected to the ground member.

12. The method according to claim 11, wherein the forming of the molding layer comprises forming a molding layer to completely cover the ground member and removing a portion of the molding layer such that a portion of the ground member is exposed out of the molding layer.

13. The method according to claim 12, wherein the removing of the portion of the molding layer comprises surface processing the molding layer using one of grinding and polishing.

14. The method according to claim 11, wherein the ground terminal comprises one of a via hole and a metal pattern.

15. The method according to claim 11, wherein the ground member comprises a metal pin.

16. The method according to claim 11, wherein the ground member comprises a wire electrically connecting the electronic device with the ground terminal.

17. The method according to claim 11, wherein the forming of the conductor layer comprises plating metal on an outer surface of the molding layer.

18. The method according to claim 12, wherein the forming of the conductor layer comprises sequentially plating a plurality of metals on a surface of the molding layer.

19. A shielding apparatus comprising:
a substrate on which an electronic device is mounted;
a molding layer on the substrate to cover the electronic device;
a conductor layer on the molding layer; and
a conducting material formed to pass through the molding layer and connect the substrate with the conductor layer.

20. A shielding apparatus comprising:
a substrate on which an electronic device is mounted;
a molding layer on the substrate to cover the electronic device;
a conductor layer on the molding layer; and
a wire in the molding layer to connect the substrate with the conductor layer.
